(19) United States
(12) Patent Application Publication
(10) Pub. No.: US 2019/0229093 A1
(43) Pub. Date: Jul. 25, 2019

(54) ELECTRONIC DEVICE PACKAGE

(71) Applicant: Intel Corporation, Santa Clara, CA (US)

(72) Inventors: Juan E. Dominguez, Chandler, AZ (US); Hyoung Il Kim, Folsom, CA (US); Mao Guo, Folsom, CA (US)

(73) Assignee: Intel Corporation, Santa Clara, CA (US)

(21) Appl. No.: 16/330,056

(22) PCT Filed: Oct. 1, 2016
(86) PCT No.: PCT/US2016/055079

§ 371 Date: Mar. 1, 2019

(51) Int. Cl. H01L 25/065; H01L 23/31; H01L 23/49; H01L 23/00; H01L 25/00

(52) U.S. Cl. CPC H01L 25/0657; H01L 23/3128; H01L 23/49; H01L 24/32; H01L 25/50; H01L 24/16; H01L 2924/014; H01L 2225/06562; H01L 2225/1058; H01L 2924/15311; H01L 2924/186; H01L 2224/1623; H01L 2224/32145

(57) ABSTRACT

Electronic device package technology is disclosed. An electronic device package can comprise a substrate. The electronic device package can also comprise first and second electronic components in a stacked configuration. Each of the first and second electronic components can include an electrical interconnect portion exposed toward the substrate. The electronic device package can further comprise a mold compound encapsulating the first and second electronic components. In addition, the electronic device package can comprise an electrically conductive post extending through the mold compound between the electrical interconnect portion of at least one of the first and second electronic components and the substrate. Associated systems and methods are also disclosed.

### TECHNICAL FIELD

Embodiments described herein relate generally to electronic device packages, and more particularly to interconnecting components in electronic device packages.

### BACKGROUND

Integrated circuit packaging often includes two or more electronic components in a stacked configuration electrically coupled to a package substrate. This arrangement provides a space savings and has therefore become increasingly popular for small form factor applications due to the higher component density that can be provided in devices such as mobile phones, personal digital assistants (PDA), and digital cameras. Electronic components in such packages are typically electrically connected to the substrate with wire bond connections.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1 illustrates a schematic cross-section of an electronic device package in accordance with an example;

FIG. 2 illustrates a schematic cross-section of an electronic device package in accordance with an example;

FIG. 3 illustrates a schematic cross-section of an electronic device package in accordance with an example;

FIGS. 4A-4E illustrates aspects of a method for making an electronic device package in accordance with an example;

FIG. 5A-5E illustrates aspects of a method for making an electronic device package in accordance with an example;

FIG. 6 illustrates aspects of a method for making an electronic device package in accordance with an example; and

FIG. 7 is a schematic illustration of an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” provide express support for plural referents unless the context clearly dictates otherwise. Thus, for example, reference to “a layer” includes a plurality of such layers.

In this application, “comprises,” “comprising,” “containing” and “having” and the like can have the meaning ascribed to them in U.S. patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. patent law. “Consisting essentially of” or “consists essentially of” have the meaning generally ascribed to them by U.S. patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. Objects described herein as being “adjacent to” each other may be in physical contact with each other, in close proximity to each other, or in the same general region or area as each other, as appropriate for the context in which the phrase is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment. Occurrences of the phrase “in one embodiment,” or “in one aspect,” herein do not necessarily all refer to the same embodiment or aspect.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

### EXAMPLE EMBODIMENTS

An initial overview of technology embodiments is provided below and specific technology embodiments are then described in further detail. This initial summary is intended to aid readers in understanding the technology embodiments more quickly but is not intended to identify key or essential features of the technology nor is it intended to limit the scope of the claimed subject matter.

Although electronic device packages with electronic component stacks are in widespread use, a typical package with stacked electronic components has electrical interconnect configurations that limit size reduction. In particular, such packages utilize wire bond connections between multiple stacked components and the package substrate, which impact package dimensions through requirements on wire bond loop height and wire sweep control during assembly processes therefore limiting minimum package profile size (e.g., in X, Y, and/or Z dimensions). In addition, new chip technologies may require higher power and frequency signal capability than wire bond technology can provide, which is limited by wire thickness conductivity and impedance over a relatively long wire.

Accordingly, an electronic device package is disclosed that minimizes or avoids wire bonding and associated space limitations for electrically interconnecting at least one electrical component in a stack with a package substrate. In one aspect, improved signal integrity of the interconnections allows higher power and higher frequency signals than that enabled by wire bonds. In one example, an electronic device package can comprise a substrate and first and second electronic components in a stacked configuration. Each of the first and second electronic components can include an electrical interconnect portion exposed toward the substrate. The electronic device package can further comprise a mold compound encapsulating the first and second electronic components. In addition, the electronic device package can comprise an electrically conductive post extending through the mold compound between the electrical interconnect portion of at least one of the first and second electronic components and the substrate. Associated systems and methods are also disclosed.

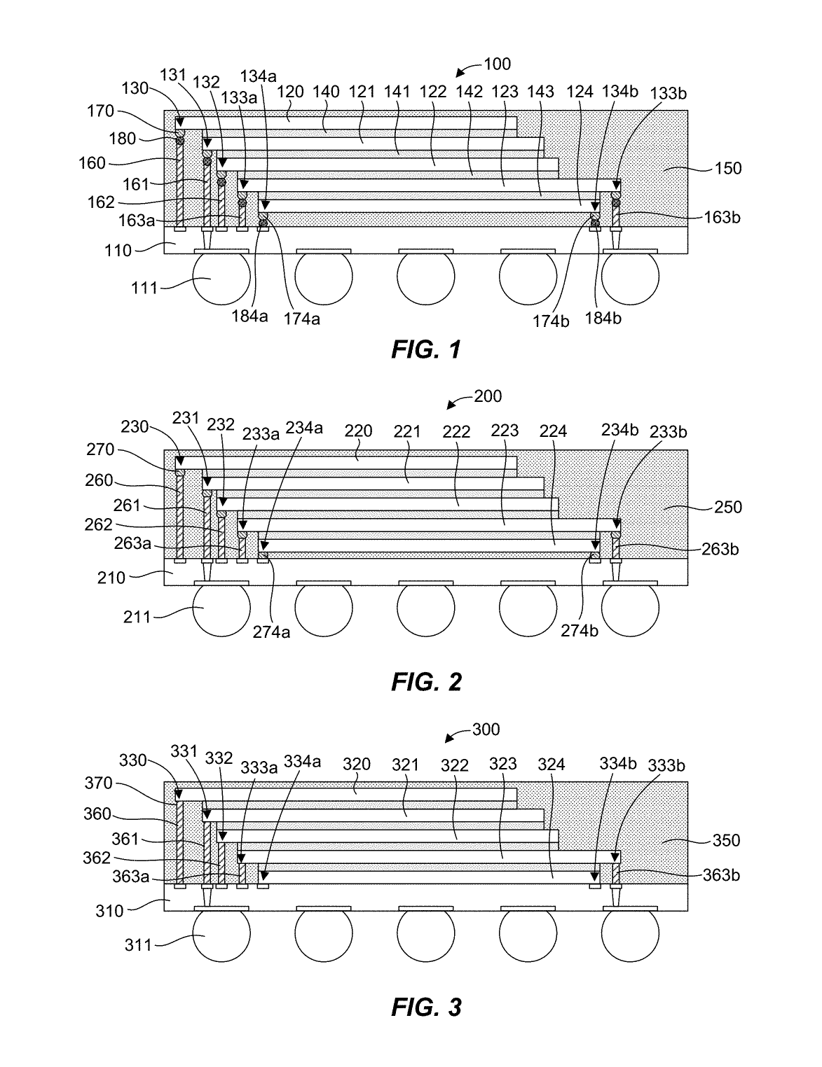

Referring to FIG. 1, an exemplary electronic device package 100 is schematically illustrated in cross-section. The electronic device package 100 can include a substrate 110. The electronic device package 100 can also include one or more electronic components (e.g. dies) 120-124, which can be operably coupled to the substrate 110. An electronic component can be any electronic device or component that may be included in an electronic device package, such as a semiconductor device (e.g., a die, a chip, a processor, computer memory, etc.). In one embodiment, each of the electronic components 120-124 may represent a discrete chip, which may include an integrated circuit. The electronic components 120-124 may be, include, or be a part of a processor, memory (e.g., ROM, RAM, EEPROM, flash memory, etc.), or an application specific integrated circuit (ASIC). In some embodiments, one or more of the electronic components 120-124 can be a system-on-chip (SOC) or a package-on-package (POP). In some embodiments, the electronic device package 100 can be a system-in-a-package (SIP).

As shown in FIG. 1, the electronic components 120-124 can be in a stacked relationship or configuration, for example, to save space and enable smaller form factors. Although five electronic components 120-124 are depicted in FIG. 1, any suitable number of electronic components can be included in a stack. While in such a stacked relationship, multiple electronic components 120-124 can include an electrical interconnect portion (e.g., including an interconnect pad such as a wire bond pad) exposed toward the substrate. In other words, electrical interconnect portions of multiple stacked electronic components 120-124 can face the substrate 110 and be unobscured by another electronic component in the stack. In the illustrated example, each of the electronic components includes an electrical interconnect portion exposed toward the substrate. For example, the electronic component 120 at the top of the stack (i.e., farthest away from the substrate 110) has an exposed electrical interconnect portion 130 facing the substrate 110 unobscured by any of the other electronic components 121-124 between the electronic component 120 and the substrate 110. The electronic component 121 has an exposed electrical interconnect portion 131 facing the substrate 110 unobscured by any of the other electronic components 122-124 between the electronic component 121 and the substrate 110. The electronic component 122 has an exposed electrical interconnect portion 132 facing the substrate 110 unobscured by any of the other electronic components 123, 124 between the electronic component 122 and the substrate 110. The electronic component 123 second from the bottom of the stack has exposed electrical interconnect portions 133a, 133b at opposite ends of the electrical component 123 facing the substrate 110 unobscured by the electronic component 124 at the bottom of the stack nearest the substrate 110. The electronic component 124 at the bottom of the stack nearest the substrate 110 has exposed electrical interconnect portions 134a, 134b at opposite ends of the electrical component 124 facing the substrate 110.

Die attach film (DAF) can be disposed between adjacent electronic components, which can provide benefits during assembly of the electronic device package 100. For example, die attach film 140 can be disposed between electronic components 120, 121, die attach film 141 can be disposed between electronic components 121, 122, die attach film 142 can be disposed between electronic components 122, 123, and die attach film 143 can be disposed between electronic components 123, 124. A mold compound material 150 (e.g., an epoxy) can encapsulate or overmold one or more of the electronic components 120-124. For example, FIG. 1 shows the mold compound 150 encapsulating all of the stacked electronic components 120-124.

The electronic components 120-124 and the substrate 110 can be electrically coupled by electrical interconnect structures including electrically conductive posts and/or solder materials (e.g., a solder ball, a solder bump, and/or a solder cap). For example, the electronic component 120 is electrically coupled to the substrate 110 with electrical interconnect structures that include a conductive post 160, a solder bump 170 (e.g., a microbump), and a solder cap 180. The electrically conductive post 160 can extend through the mold compound 150 between the electrical interconnect portion 130 and the substrate 110. In one aspect, the solder bump 170 can be associated with the electrical interconnect portion 130, the solder cap 180 can be associated with the solder bump 170, and the electrically conductive post 160 can extend from the substrate 110 and terminate at the solder cap 180. In one embodiment, an electrically conductive post can be a through-mold via. The electronic components 121-123 are similarly connected to the substrate 110 with conductive posts extending through the mold compound 150 between the electrical interconnect portions and the substrate 110. For example, the electronic component 121 is connected to the substrate 110 with a conductive post 161 extending through the mold compound 150 between the electrical interconnect portion 131 and the substrate 110. The electronic component 122 is connected to the substrate 110 with a conductive post 162 extending through the mold compound 150 between the electrical interconnect portion 132 and the substrate 110. The electronic component 123 is connected to the substrate 110 with conductive posts 163a, 163b extending through the mold compound 150 between the electrical interconnect portions 133a, 133b, respectively, and the substrate 110. Solder materials for these connections are not individually labeled. The electronic component 124 is connected to the substrate 110 by solder materials (e.g., solder bumps 174a, 174b and solder caps 184a, 184b) but lacks a conductive post due to its proximity to the substrate 110. The conductive posts can have any suitable length, which may be the same as another conductive post or different from another conductive post, and may be influenced by the length or thickness of the solder material, which may also be the same or vary relative to other solder material features (e.g., solder bumps).

The interconnect structures (e.g., electrically conductive post 160, solder bump 170, and solder cap 1180) can be configured to route electrical signals between the electronic components 120-124 and the substrate 110. In some embodiments, the interconnect structures may be configured to route electrical signals such as, for example, I/O signals and/or power or ground signals associated with the operation of the electronic components 120-124. An electrically conductive post can be made of any suitable conductive material, (e.g., a metal material such as copper). In one aspect, an electrically conductive post can have a thickness or diameter greater than about 50 μm. An electrically conductive post can have a constant or varying thickness or diameter along its length. In another aspect, an electrically conductive post can have a resistance of less than about 0.1 ohms. Any suitable solder material can be utilized, such as silver and/or tin.

Exposing the electrical interconnect portions 130-134b of the stacked electronic devices 120-124 toward the substrate 110, such as by laterally offsetting the stacked components, can facilitate the use of straight or linear interconnect features for coupling with the substrate 110 that can replace typical wire bond connections. Such interconnect features can also have relatively large thickness or diameter and relatively low resistance compared to typical wire bond connections, which can provide improved signal integrity as well as higher frequency and power transmission capabilities than that of wire bond connections. The use of conductive posts and solder material (e.g., solder bumps) as disclosed herein can therefore provide an alternative to the use of space consuming wire bond connections and expensive through-silicon vias for interconnection of electronic components and substrates, which can provide for reduced package size and/or costs, as well as increased performance.

The substrate 110 may include typical substrate materials. For example, the substrate may comprise an epoxy-based laminate substrate having a core and/or build-up layers. The substrate 110 may include other suitable types of materials in other embodiments. For example, the substrate can be formed primarily of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, such as can be used in printed circuit boards (PCBs).

The substrate 110 may include electrical routing features configured to route electrical signals to or from the electronic components 120-124. The electrical routing features may be internal and/or external to the substrate 110. For example, in some embodiments, the substrate 110 may include electrical routing features such as pads, vias, and/or traces as commonly known in the art, configured to receive the interconnect structures (e.g., electrically conductive post 160) and route electrical signals to or from the electronic components 120-124. The pads, vias, and traces of the substrate 110 can be constructed of the same or similar electrically conductive materials, or of different electrically conductive materials. In one aspect, the substrate 110 can be configured as a redistribution layer.

In one aspect, the substrate 110 can be configured to facilitate electrically coupling the electronic device package 100 with an external electronic component, such as another substrate (e.g., a circuit board such as a motherboard) to further route electrical signals and/or to provide power. The electronic device package 100 can include interconnects, such as solder balls 111, coupled to the substrate 110 for electrically coupling the electronic device package 100 with an external electronic component.

FIG. 2 schematically illustrates a cross-section of an electronic device package 200 in accordance with another example of the present disclosure. The electronic device package 200 is similar to the electronic device package 100 of FIG. 1 in many respects. For example, the electronic device package 200 includes electronic components 220-224 in a stacked arrangement with multiple electronic components having electrical interconnect portions exposed toward a substrate 210. In addition, the electronic components 220-224 are encapsulated in a mold compound material 250 and conductive posts extend through the mold compound between the electrical interconnect portions and the substrate 210.

In particular, the electronic component 220 is electrically coupled to the substrate 210 with electrical interconnect structures that include a conductive post 260 and a solder bump 270 (e.g., a microbump). The electrically conductive post 260 can extend through the mold compound 250 between an electrical interconnect portion 230 and the substrate 210. In one aspect, the solder bump 270 can be associated with the electrical interconnect portion 230. The electronic components 221-223 are similarly connected to the substrate 210. For example, the electronic component 221 is connected to the substrate 210 with a conductive post 261 extending through the mold compound 250 between an electrical interconnect portion 231 and the substrate 210. The electronic component 222 is connected to the substrate 210 with a conductive post 262 extending through the mold compound 250 between an electrical interconnect portion 232 and the substrate 210. The electronic component 223 is connected to the substrate 210 with conductive post 263a, 263b extending through the mold compound 250 between electrical interconnect portions 233a, 233b, respectively, and the substrate 210. Solder bumps for these connections are not individually labeled. The electronic component 224 is connected to the substrate 210 by solder bumps 274a, 274b but lacks a conductive post due to its proximity to the substrate 210.

In this case, the electrical interconnect structures of the electronic device package 200 lack the solder caps of the electronic device package 100 that are associated with solder bumps and facilitate or provide connections with the conductive posts. Accordingly, the electrically conductive posts 260-263b extend through the mold compound 250 and terminate at the solder bumps.

FIG. 3 schematically illustrates a cross-section of an electronic device package 300 in accordance with another example of the present disclosure. The electronic device package 300 is similar to the electronic device package 100 of FIG. 1 and the electronic device package 200 of FIG. 2 in many respects. For example, the electronic device package 300 includes electronic components 320-324 in a stacked arrangement with multiple electronic components having electrical interconnect portions exposed toward a substrate 310. In addition, the electronic components 320-324 are encapsulated in a mold compound material 350 and conductive posts extend through the mold compound between the electrical interconnect portions and the substrate 310.

In particular, the electronic component 320 is electrically coupled to the substrate 310 with electrical interconnect structures that include a conductive post 360. The electrically conductive post 360 can extend through the mold compound 350 between an electrical interconnect portion 330 and the substrate 310. The electronic components 321-323 are similarly connected to the substrate 310. For example, the electronic component 321 is connected to the substrate 310 with a conductive post 361 extending through the mold compound 350 between an electrical interconnect portion 331 and the substrate 310. The electronic component 322 is connected to the substrate 310 with a conductive post 362 extending through the mold compound 350 between an electrical interconnect portion 332 and the substrate 310. The electronic component 323 is connected to the substrate 310 with conductive post 363a, 363b extending through the mold compound 350 between electrical interconnect portions 333a, 333b, respectively, and the substrate 310.

In this case, the electrical interconnect structures of the electronic device package 300 lack the solder bumps of the electronic device packages 100, 200 and the solder caps of the electronic device package 100, which can provide connections with conductive posts. Instead, the conductive posts are coupled directly to their respective components 321-323. Accordingly, the electrically conductive posts 360-363b extend through the mold compound 250 and terminate at the electrical interconnect portions 330-333b and the substrate 310. In other words, the conductive posts extend from the electrical interconnect portions 330-333b and the substrate 310. In addition, the electronic component 324 is connected directly to the substrate 310 (e.g., to an interconnect pad).

The electronic device packages 100, 200, 300 demonstrate that solder bumps and solder caps can be utilized as desired in conjunction with conductive posts in an electronic device package of the present disclosure, and any combination of conductive posts, solder caps, and/or solder bumps can be used at any location in order to achieve a specific result, or configuration in a given device.

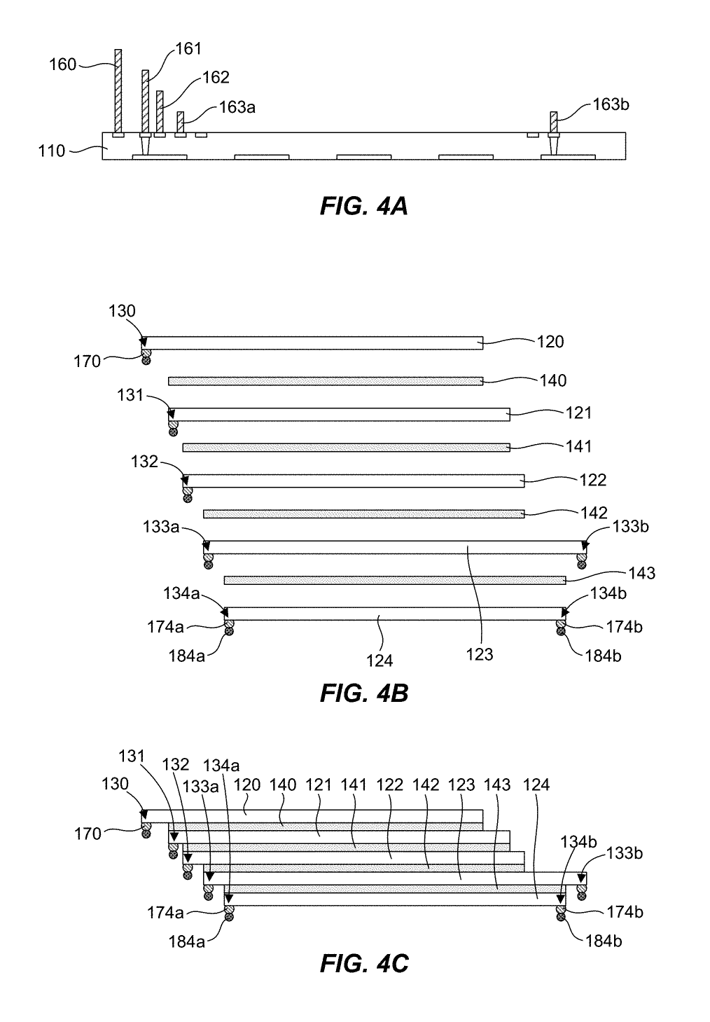

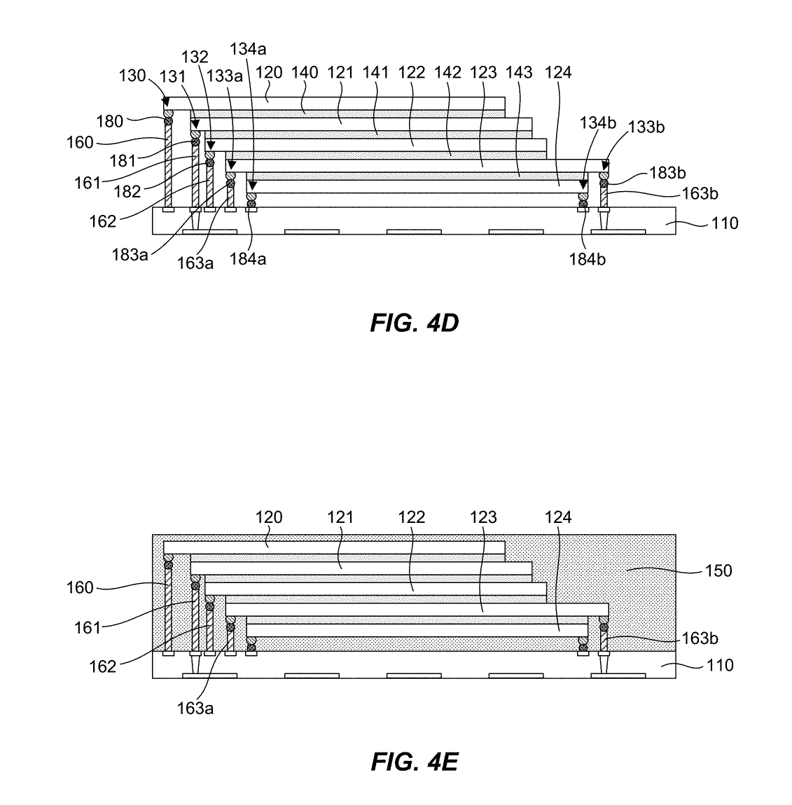

FIGS. 4A-6 illustrate aspects of exemplary methods or processes for making an electronic device package. FIGS. 4A-4E illustrate aspects of a method for making an electronic device package in accordance with one example of the present disclosure, such as the electronic device package 100. FIG. 4A schematically illustrates a side cross-sectional view of the substrate 110 of an electronic component. Electrically conductive posts 160-163b can be disposed on the substrate 110, such as on interconnects pads. The conductive posts can be disposed on the substrate 110 utilizing any suitable technique or process. For example, the conductive posts can be “grown” on the substrate utilizing a deposition process (e.g., plating, printing, sputtering, etc.). Lengths or heights of the conductive posts extending from the substrate 110 can be the same or different. For example, the conductive posts 160, 161, 162, and 163a can each have a different length. Length variation of the conductive posts can be accomplished by changing the current density on a particular substrate area and/or by a material removal process (e.g., polishing). The conductive posts can be terminated with a solder cap (not shown), as desired. The configuration illustrated in FIG. 4A represents one embodiment of an electronic device package precursor. An electronic device package precursor can be subjected to further processing as disclosed herein to create an electronic device package in accordance with the present disclosure.

As shown in FIGS. 4B and 4C, electronic components 120-124 can be arranged in a stacked configuration. Multiple electronic components in the stack can include exposed electrical interconnect portions unobscured by any of the other electronic components in the stack. For example, the electronic component 120 has exposed electrical interconnect portion 130, the electronic component 121 has exposed electrical interconnect portion 131, the electronic component 122 has exposed electrical interconnect portion 132, the electronic component 123 has exposed electrical interconnect portions 133a, 133b at opposite ends of the electrical component 123, and the electronic component 124 has exposed electrical interconnect portions 134a, 134b at opposite ends of the electrical component 124.

In one aspect, die attach film can optionally be disposed between two or more of the electronic components to assist in stacking of the electronic components 120-124. For example, the die attach film 140 can be disposed between electronic components 120, 121, the die attach film 141 can be disposed between electronic components 121, 122, the die attach film 142 can be disposed between electronic components 122, 123, and the die attach film 143 can be disposed between electronic components 123, 124.

In one aspect, solder material can be associated with the electrical interconnect portions. For example, a solder bump (e.g., a microbump) can be disposed on one or more of the electrical interconnect portions. Solder material can be disposed on an electrical interconnect portion utilizing any suitable technique or process, such as a deposition process (e.g., plating, printing, sputtering, etc.). The stack of electronic components can include solder bumps with the same height or different heights. The solder bumps can be made to be different heights by any suitable technique or process, such as by varying the solder deposition thickness or dual patterning and dual plating. In one aspect, one or more of the electronic components may not have a solder bump associated with an electrical interconnect portion at this stage of manufacture. In addition, a solder cap can be disposed on the solder bump. This is exemplified by the solder cap 180 disposed on the solder bump 170, which is associated with the electrical interconnect portion 130 of the electronic component 120, and by the solder caps 184a, 184b disposed on the solder bumps 174a, 174b, which are associated with the electrical interconnect portions 134a, 134b of the electronic component 124. Thus, a solder bump can be terminated with a solder cap or tip, as desired, to facilitate assembly as described below.

As shown in FIG. 4D, the electrically conductive posts 160-163b can be electrically coupled to the respective electrical interconnect portions 130-133b of the electronic components 120-123. Thus, the electrically conductive posts 160-163b can terminate at the solder material (e.g., the solder caps 180-183b) when electrically coupled to the respective electrical interconnect portions 130-133b. In addition, the solder caps 184a, 184b associated with the electronic component 124 can be electrically coupled to the substrate 110. Thus, after stacking the electronic components 120-124, the stacked assembly can be coupled to the conductive posts 160-163b on the substrate 110. Such coupling of the electrical interconnect portions and the conductive posts can be accomplished using any suitable technique or process, such as thermal compression bonding, mass reflow, or other similar techniques.

The configuration illustrated in FIG. 4D represents another embodiment of an electronic device package precursor, where the electronic components 120-124 are in a stacked configuration and the electrical interconnect portions of multiple electronic components are exposed toward the substrate 110, and the electrically conductive posts 160-163b extend between the electrical interconnect portions 130-133b of the electronic components and the substrate 110. In one aspect of an electronic device package precursor, the electrically conductive posts 160-163b terminate at the solder material (e.g., the solder caps 180-183b). In another aspect of an electronic device package precursor, the die attach film 140-143 is disposed between two or more of the electronic components 120-124.

In one aspect of a method for making an electronic device package, the electronic components 120-124 and associated electrical interconnect structures (e.g., the electrically conductive posts 160-163b and solder materials) can be encapsulated in the mold compound 150, as shown in FIG. 4E. Solder balls (e.g., the solder balls 111) can also be added to the substrate 110 to provide the electronic device package 100 as shown in FIG. 1.

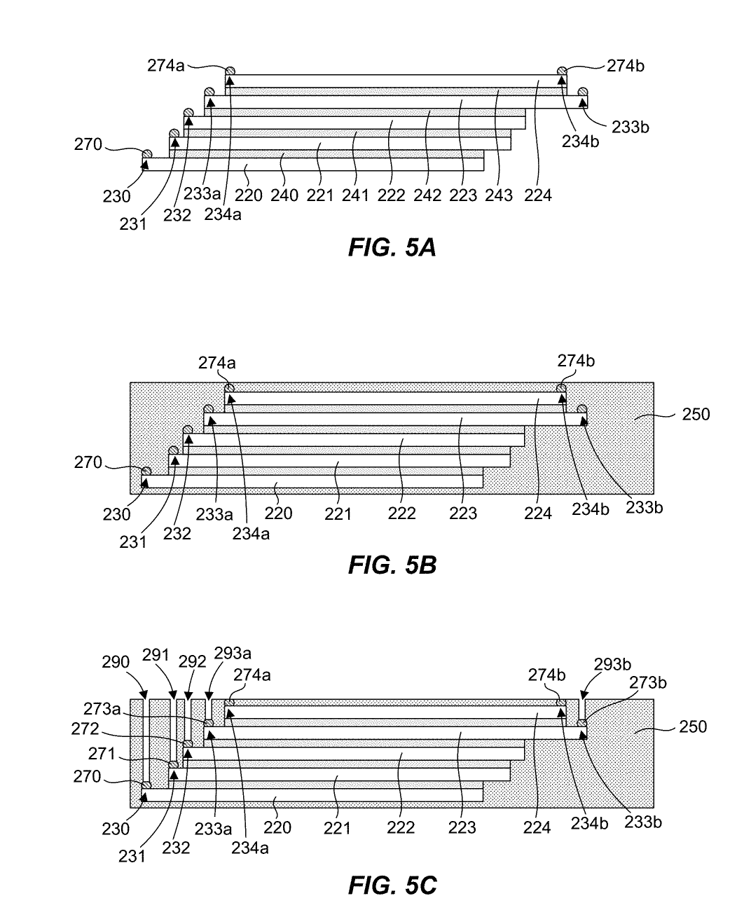

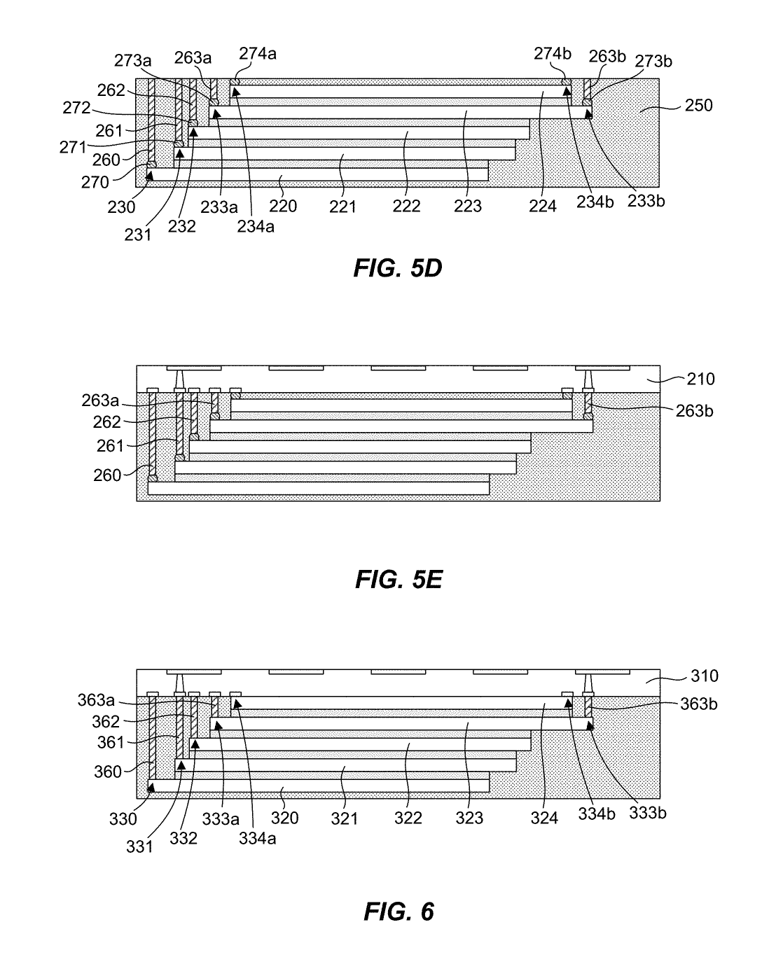

FIGS. 5A-5E illustrate aspects of a method for making an electronic device package in accordance with one example of the present disclosure, such as the electronic device package 200. FIG. 5A illustrates electronic components 220-224 arranged in a stacked configuration. Multiple electronic components in the stack can include exposed electrical interconnect portions unobscured by any of the other electronic components in the stack. For example, the electronic component 220 has exposed electrical interconnect portion 230, the electronic component 221 has exposed electrical interconnect portion 231, the electronic component 222 has exposed electrical interconnect portion 232, the electronic component 223 has exposed electrical interconnect portions 233a, 233b at opposite ends of the electrical component 223, and the electronic component 224 has exposed electrical interconnect portions 234a, 234b at opposite ends of the electrical component 224.

In one aspect, die attach film can optionally be disposed between two or more of the electronic components to assist in stacking of the electronic components 220-224. For example, die attach film 240 can be disposed between electronic components 220, 221, die attach film 241 can be disposed between electronic components 221, 222, die attach film 242 can be disposed between electronic components 222, 223, and die attach film 243 can be disposed between electronic components 223, 224.

In one aspect, solder material (e.g., solder bumps 270, 274a, 274b) can be associated with the electrical interconnect portions. For example, a solder bump (e.g., a microbump) can be disposed on one or more of the electrical interconnect portions. Solder material can be disposed on an electrical interconnect portion utilizing any suitable technique or process, such as a deposition process (e.g., plating, printing, sputtering, etc.). The stack of electronic components can include solder bumps with the same height or different heights.

As shown in FIG. 5B, the stacked electronic components 220-224 and associated electrical interconnect structures (e.g., the solder bumps) can be encapsulated or over-molded in the mold compound 250. An opening can be formed extending through the mold compound 250 to the electrical interconnect portion of one or more of the electronic components 220-223 (i.e., terminating at the solder bumps 270-273b), as shown in FIG. 5C. An opening can be formed in the mold compound 250 by any suitable technique or process, such as laser drilling, etching (e.g., deep reactive ion etching), etc. For example, openings 290-293b can be formed extending through the mold compound 250 to the respective electrical interconnect portions 230-233b. The depth of the openings 290-293b in the mold compound 250 can be the same or different, which may depend on the location of the electrical interconnect portions 230-233b in the stack of electronic components 220-224 and the thickness or length of the solder bumps 270-273b.

The configuration illustrated in FIG. 5C represents an embodiment of an electronic device package precursor, where the electronic components 220-224 are in a stacked configuration with exposed electrical interconnect portions 230-233b of multiple electronic components 220-223, mold compound 250 encapsulates the electronic components, and an opening (e.g., openings 290-293b) extends through the mold compound to the electrical interconnect portion of one or more of the electronic components. In one aspect of an electronic device package precursor, solder material (e.g., the solder bumps 270-273b) is associated with one or more of the electrical interconnect portions. In another aspect of an electronic device package precursor, the die attach film 240-243 is disposed between two or more of the electronic components 220-224.

As shown in FIG. 5D, the electrically conductive posts 260-263b can be disposed in the openings 290-293b in the mold compound 250 such that the conductive posts are electrically coupled to the respective electrical interconnect portions 230-233b of the electronic components 220-223, forming through-mold vias. Thus, the electrically conductive posts 260-263b can terminate at the solder material (e.g., the solder bumps 270-273b) when electrically coupled to the respective electrical interconnect portions 230-233b. In one aspect, the conductive posts 260-263b can be formed by depositing conductive material in the openings 290-293b. Conductive material can be deposited in the openings 290-293b by any suitable technique or process, such as plating, printing, sputtering, etc. In one embodiment, solder material can be deposited in the openings 290-293b to form the conductive posts 260-263b. Because the depth of the openings 290-293b in the mold compound 250 can be the same or different, lengths of the conductive posts 260-263b disposed or formed in the openings can be the same or different.

The configuration illustrated in FIG. 5D represents another embodiment of an electronic device package precursor, where the electronic components 220-224 are in a stacked configuration with exposed electrical interconnect portions 230-233b of multiple electronic components 220-223, mold compound 250 encapsulates the electronic components, an opening (e.g., openings 290-293b) extends through the mold compound to the electrical interconnect portion of one or more of the electronic components, and an electrically conductive post (e.g., electrically conductive posts 260-263b) is disposed in the opening in the mold compound 250. In one aspect of an electronic device package precursor, solder material (e.g., the solder bumps 270-273b) is associated with one or more of the electrical interconnect portions and the electrically conductive post terminates at the solder material.

In one aspect of a method for making an electronic device package, the substrate 210 can be electrically coupled to the electrically conductive posts 260-263b, such as to interconnects pads of the substrate 210, as shown in FIG. 5E. Such coupling of the conductive posts 260-263b and the substrate 210 can be accomplished using any suitable technique or process, such as thermal compression bonding, mass reflow, or other similar techniques. In some embodiments, solder caps (not shown) can be used to electrically couple the conductive posts 260-263b and the substrate 210. Solder balls (e.g., the solder balls 211) can also be added to the substrate 210 to provide the electronic device package 200 as shown in FIG. 2.

FIG. 6 illustrates aspects of a method for making an electronic device package in accordance with another example of the present disclosure, such as the electronic device package 300. This method and associated electronic device package precursors are similar to method and precursors shown and described with respect to FIGS. 5A-5D. In this case, no solder material (e.g., solder bumps or solder caps) is associated with the electrical interconnect portions 330-333b of the electronic components 320-323. Thus, openings in the mold compound 350 terminate at the electrical interconnect portions 330-333b. Accordingly, the conductive posts 360-363b in the openings terminate at the electrical interconnect portions 330-333b and the substrate 310 (e.g., on interconnects pads). Solder balls (e.g., the solder balls 311) can also be added to the substrate 310 to provide the electronic device package 300 as shown in FIG. 3.

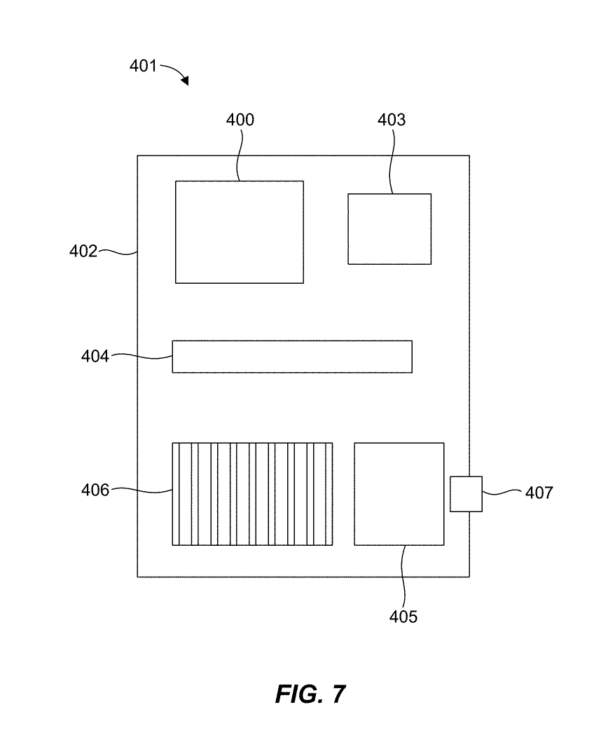

FIG. 7 schematically illustrates an example computing system 401. The computing system 401 can include an electronic device package 400 as disclosed herein, coupled to a motherboard 402. In one aspect, the computing system 401 can also include a processor 403, a memory device 404, a radio 405, a cooling system (e.g., a heat sink and/or a heat spreader) 406, a port 407, a slot, or any other suitable device or component, which can be operably coupled to the motherboard 402. The computing system 401 can comprise any type of computing system, such as a desktop computer, a laptop computer, a tablet computer, a smartphone, a server, a wearable electronic device, etc. Other embodiments need not include all of the features specified in FIG. 7, and may include alternative features not specified in FIG. 7.

### EXAMPLES

The following examples pertain to further embodiments.

In one example there is provided, an electronic device package comprising a substrate, first and second electronic components in a stacked configuration, wherein each of the first and second electronic components includes an electrical interconnect portion exposed toward the substrate, a mold compound encapsulating the first and second electronic components, and an electrically conductive post extending through the mold compound between the electrical interconnect portion of at least one of the first and second electronic components and the substrate.

In one example of an electronic device package, the electrically conductive post extends from the substrate.

In one example, an electronic device package comprises a solder material, wherein the electrically conductive post terminates at the solder material.

In one example of an electronic device package, the solder material comprises at least one of a solder bump and a solder cap.

In one example of an electronic device package, the solder material comprises silver, tin, or a combination thereof.

In one example of an electronic device package, the solder bump comprises a microbump.

In one example of an electronic device package, the solder bump is associated with the electrical interconnect portion.

In one example of an electronic device package, the solder cap is associated with the solder bump.

In one example of an electronic device package, the electrically conductive post extends from the electrical interconnect portion.

In one example, an electronic device package comprises a die attach film disposed between the first and second electronic components.

In one example of an electronic device package, the electrically conductive post has a thickness greater than about 50 μm.

In one example of an electronic device package, the electrically conductive post has a resistance less than about 0.1 ohms.

In one example of an electronic device package, the electrically conductive post comprises a metal material.

In one example of an electronic device package, the metal material comprises copper.

In one example of an electronic device package, the mold compound comprises an epoxy.

In one example, there is provided an electronic device package precursor comprising a substrate, and electrically conductive posts of different lengths extending from the substrate.

In one example, an electronic device package precursor comprises first and second electronic components in a stacked configuration, each of the first and second electronic components including an electrical interconnect portion exposed toward the substrate, wherein the electrically conductive posts extend between the electrical interconnect portions of the first and second electronic components and the substrate.

In one example, an electronic device package precursor comprises solder material associated with the electrical interconnect portions, wherein the electrically conductive posts terminate at the solder material.

In one example of an electronic device package precursor, the solder material comprises silver, tin, or a combination thereof.

In one example of an electronic device package precursor, the solder material comprises at least one of a solder bump and a solder cap.

In one example of an electronic device package precursor, the solder bump comprises a microbump.

In one example of an electronic device package precursor, the solder cap is associated with the solder bump.

In one example, an electronic device package precursor comprises a die attach film disposed between the first and second electronic components.

In one example of an electronic device package precursor, each of the electrically conductive posts has a thickness greater than about 50 μm.

In one example of an electronic device package precursor, each of the electrically conductive posts has a resistance less than about 0.1 ohms.

In one example of an electronic device package precursor, the electrically conductive posts comprise a metal material.

In one example of an electronic device package precursor, the metal material comprises copper.

In one example, there is provided an electronic device package precursor comprising first and second electronic components in a stacked configuration, wherein each of the first and second electronic components includes an exposed electrical interconnect portion, a mold compound encapsulating the first and second electronic components, and an opening extending through the mold compound to the electrical interconnect portion of at least one of the first and second electronic components.

In one example, an electronic device package precursor comprises solder material associated with the electrical interconnect portions.

In one example of an electronic device package precursor, the solder material comprises silver, tin, or a combination thereof.

In one example of an electronic device package precursor, the solder material comprises at least one of a solder bump and a solder cap.

In one example of an electronic device package precursor, the solder bump comprises a microbump.

In one example of an electronic device package precursor, the solder cap is associated with the solder bump.

In one example, an electronic device package precursor comprises a die attach film disposed between the first and second electronic components.

In one example, an electronic device package precursor comprises an electrically conductive post disposed in the opening in the mold compound.

In one example of an electronic device package precursor, the electrically conductive post has a thickness greater than about 50 μm.

In one example of an electronic device package precursor, the electrically conductive post has a resistance less than about 0.1 ohms.

In one example of an electronic device package precursor, the electrically conductive post comprises a metal material.

In one example of an electronic device package precursor, the metal material comprises copper.

In one example, there is provided a computing system comprising a motherboard, and an electronic device package operably coupled to the motherboard. The electronic device package comprises a substrate, first and second electronic components in a stacked configuration, wherein each of the first and second electronic components includes an electrical interconnect portion exposed toward the substrate, a mold compound encapsulating the first and second electronic components, and an electrically conductive post extending through the mold compound between the electrical interconnect portion of at least one of the first and second electronic components and the substrate.

In one example of a computing system, the computing system comprises a desktop computer, a laptop, a tablet, a smartphone, a server, a wearable electronic device, or a combination thereof.

In one example of a computing system, the computing system further comprises a processor, a memory device, a heat sink, a radio, a slot, a port, or a combination thereof operably coupled to the motherboard.

In one example there is provided a method for making an electronic device package comprising providing a substrate, disposing a first electrically conductive post on the substrate, and disposing a second electrically conductive post on the substrate, wherein lengths of the first and second conductive posts are different.

In one example. a method for making an electronic device package comprises arranging first and second electronic components in a stacked configuration, wherein each of the first and second electronic components include an exposed electrical interconnect portion, and electrically coupling the first and second electrically conductive posts to the electrical interconnect portions of the first and second electronic components, respectively.

In one example. a method for making an electronic device package comprises associating solder material with the electrical interconnect portions, wherein the first and second electrically conductive posts terminate at the solder material when electrically coupled to the respective electrical interconnect portions.

In one example of a method for making an electronic device package, the solder material comprises silver, tin, or a combination thereof.

In one example of a method for making an electronic device package, associating solder material with the electrical interconnect portions comprises disposing a solder bump on at least one of the electrical interconnect portions.

In one example of a method for making an electronic device package, associating solder material with the electrical interconnect portions further comprises disposing a solder cap on the solder bump.

In one example of a method for making an electronic device package, the solder bump comprises a microbump.

In one example. a method for making an electronic device package comprises disposing a die attach film between the first and second electronic components.

In one example. a method for making an electronic device package comprises encapsulating the first and second electronic components in a mold compound.

In one example of a method for making an electronic device package, each of the electrically conductive posts has a thickness greater than about 50 μm.

In one example of a method for making an electronic device package, each of the electrically conductive posts has a resistance less than about 0.1 ohms.

In one example of a method for making an electronic device package, the electrically conductive posts comprise a metal material.

In one example of a method for making an electronic device package, the metal material comprises copper.

In one example there is provided a method for making an electronic device package comprising arranging first and second electronic components in a stacked configuration, wherein each of the first and second electronic components include an exposed electrical interconnect portion, encapsulating the first and second electronic components in a mold compound, and forming an opening extending through the mold compound to the electrical interconnect portion of at least one of the first and second electronic components.

In one example. a method for making an electronic device package comprises associating solder material with the electrical interconnect portions.

In one example of a method for making an electronic device package, the solder material comprises silver, tin, or a combination thereof.

In one example of a method for making an electronic device package, associating solder material with the electrical interconnect portions comprises disposing a solder bump on at least one of the electrical interconnect portions.

In one example of a method for making an electronic device package, the solder bump comprises a microbump.

In one example. a method for making an electronic device package comprises disposing a die attach film between the first and second electronic components.

In one example. a method for making an electronic device package comprises disposing an electrically conductive post in the opening in the mold compound such that the electrically conductive post is electrically coupled to the electrical interconnect portion of at least one of the first and second electronic components.

In one example of a method for making an electronic device package, the electrically conductive post has a thickness greater than about 50 μm.

In one example of a method for making an electronic device package, the electrically conductive post has a resistance less than about 0.1 ohms.

In one example of a method for making an electronic device package, the electrically conductive post comprises a metal material.

In one example of a method for making an electronic device package, the metal material comprises copper.

In one example. a method for making an electronic device package comprises electrically coupling a substrate to the electrically conductive post.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. An electronic device package, comprising:
a substrate;
first and second electronic components in a stacked configuration, wherein each of the first and second electronic components includes an electrical interconnect portion exposed toward the substrate;
a mold compound encapsulating the first and second electronic components; and
an electrically conductive post extending through the mold compound between the electrical interconnect portion of at least one of the first and second electronic components and the substrate.

2. The electronic device package of claim 1, wherein the electrically conductive post extends from the substrate.

3. The electronic device package of claim 2, further comprising a solder material, wherein the electrically conductive post terminates at the solder material.

4. The electronic device package of claim 2, wherein the solder material comprises at least one of a solder bump and a solder cap.

5. The electronic device package of claim 4, wherein the solder material comprises silver, tin, or a combination thereof.

6. The electronic device package of claim 4, wherein the solder bump comprises a microbump.

7. The electronic device package of claim 4, wherein the solder bump is associated with the electrical interconnect portion.

8. The electronic device package of claim 7, wherein the solder cap is associated with the solder bump.

9. The electronic device package of claim 1, wherein the electrically conductive post extends from the electrical interconnect portion.

10. The electronic device package of claim 1, further comprising a die attach film disposed between the first and second electronic components.

11. The electronic device package of claim 1, wherein the electrically conductive post has a thickness greater than about 50 μm.

12. The electronic device package of claim 1, wherein the electrically conductive post has a resistance less than about 0.1 ohms.

13. The electronic device package of claim 1, wherein the electrically conductive post comprises a metal material.

14. The electronic device package of claim 13, wherein the metal material comprises copper.

15. The electronic device package of claim 1, wherein the mold compound comprises an epoxy.

16-39. (canceled)

40. A computing system, comprising:
a motherboard; and
an electronic device package as in claim 1 operably coupled to the motherboard.

41. The system of claim 41, wherein the computing system comprises a desktop computer, a laptop, a tablet, a smartphone, a server, a wearable electronic device, or a combination thereof.

42. The system of claim 41, further comprising a processor, a memory device, a heat sink, a radio, a slot, a port, or a combination thereof operably coupled to the motherboard.

43. A method for making an electronic device package, comprising:
providing a substrate;
disposing a first electrically conductive post on the substrate; and
disposing a second electrically conductive post on the substrate, wherein lengths of the first and second conductive posts are different.

44. The method of claim 43, further comprising:
arranging first and second electronic components in a stacked configuration, wherein each of the first and second electronic components include an exposed electrical interconnect portion; and
electrically coupling the first and second electrically conductive posts to the electrical interconnect portions of the first and second electronic components, respectively.

45. The method of claim 44, further comprising associating solder material with the electrical interconnect portions, wherein the first and second electrically conductive posts terminate at the solder material when electrically coupled to the respective electrical interconnect portions.

46. (canceled)

47. The method of claim 45, wherein associating solder material with the electrical interconnect portions comprises disposing a solder bump on at least one of the electrical interconnect portions.

48. The method of claim 47, wherein associating solder material with the electrical interconnect portions further comprises disposing a solder cap on the solder bump.

49. The method of claim 47, wherein the solder bump comprises a microbump.

50. The method of claim 44, further comprising disposing a die attach film between the first and second electronic components.

51. The method of claim 44, further comprising encapsulating the first and second electronic components in a mold compound.

52. The method of claim 43, wherein each of the electrically conductive posts has a thickness greater than about 50 μm.

53. The method of claim 43, wherein each of the electrically conductive posts has a resistance less than about 0.1 ohms.

54-67. (canceled)
